(19) United States
(12) Patent Application Publication
(10) Pub. No.: US 2025/0015022 A1
(43) Pub. Date: Jan. 9, 2025

(54) FABRICATION METHOD FOR SEMICONDUCTOR STRUCTURE AND SEMICONDUCTOR STRUCTURE

(71) Applicant: SiPLP Microelectronics (Chongqing) Limited, Chongqing (CN)

(72) Inventors: Yan HUO, Chongqing (CN); Wenwu ZHOU, Chongqing (CN)

(21) Appl. No.: 18/846,234

(22) PCT Filed: Apr. 28, 2022
(86) PCT No.: PCT/CN2022/089782

§ 371 Date: Sep. 11, 2024

(30) Foreign Application Priority Data
Aug. 16, 2021 (CN) 202110937621.2

(51) Int. Cl. H01L 23/00; H01L 25/065

(52) U.S. Cl. CPC H01L 24/02; H01L 24/08; H01L 24/05; H01L 24/32; H01L 25/0655; H01L 2224/0231; H01L 2224/02331; H01L 2224/02333; H01L 2224/02381; H01L 2224/05554; H01L 2224/05555; H01L 2224/08245; H01L 2224/32225; H01L 2924/1815

(57) ABSTRACT

The present application provides a fabrication method for a semiconductor structure and a semiconductor structure. The fabrication method comprises: providing a structure to be wired, the structure comprising at least one chip, the chip having a front surface, and the front surface of the chip being provided with a plurality of solder pads; forming a first insulating layer on the front surface of the chip, the first insulating layer being provided with a plurality of openings, and each opening exposing at least part of one solder pad; forming a conductive film layer on the side of the first insulating layer distant from the chip; removing the part of the conductive film layer that exceeds the first insulating layer; and forming a rewiring structure on the side of the first insulating layer distant from the chip.

### TECHNICAL FIELD

The present disclosure relates to the field of semiconductor technologies, and in particular, to a fabrication method for a semiconductor structure, and a semiconductor structure.

### BACKGROUND

A semiconductor structure usually includes a chip and a redistribution layer located on a front surface of the chip, where the front surface of the chip is provided with a pad and an insulating layer above the pad, the insulating layer is provided with an opening exposing the pad, and the redistribution layer is electrically connected to the pad through a conductive structure in the opening. In common fabrication technologies for semiconductor structures, the redistribution layer and a conductive portion are formed simultaneously.

Existing fabrication technologies for semiconductor structures produce semiconductor structures with low yield.

### SUMMARY

Embodiments of the present application provide a fabrication method for a semiconductor structure and a semiconductor structure.

A first aspect of the embodiments of the present application provides a fabrication method for a semiconductor structure. The fabrication method for the semiconductor structure includes:
providing a to-be-wired structure, where the to-be-wired structure includes at least one chip, the chip includes a front surface, and the front surface of the chip is provided with pads;
forming a first insulating layer on the front surface of the chip, where the first insulating layer is provided with openings, and each of the openings exposes at least part of one of the pads;
forming a conductive film layer on a side of the first insulating layer facing away from the chip, where the conductive film layer covers a surface of the first insulating layer facing away from the chip and portions of the pads exposed by the openings, and a thickness of a portion of the conductive film layer located on the side of the first insulating layer facing away from the chip is less than a thickness of a portion of the conductive film layer covering the pads;
removing a portion of the conductive film layer exceeding the first insulating layer to obtain conductive structures located in the openings and in direct contact with the pads; and
forming a redistribution structure on the side of the first insulating layer facing away from the chip, where the redistribution structure is electrically connected to the conductive structures.

A second aspect of the embodiments of the present application provides a semiconductor structure, including:
a to-be-wired structure, where the to-be-wired structure includes at least one chip, the chip includes a front surface, and the front surface of the chip is provided with pads;
a first insulating layer on the front surface of the chip, where the first insulating layer is provided with openings, and each of the openings exposes at least part of one of the pads;
conductive structures located in the openings and in direct contact with the pads;
a redistribution structure located on a side of the first insulating layer facing away from the chip, where the redistribution structure includes wirings, and the wirings are in direct contact with the conductive structures; for each of the wirings and each of the conductive structures, a width of a portion of the wiring in contact with the conductive structure is less than a width of a surface of the conductive structure facing away from the chip.

A primary technical effect to be achieved by the embodiments of the present application includes:

According to the fabrication method for the semiconductor structure and the semiconductor structure provided by the embodiments of the present disclosure, in a fabrication process of the semiconductor structure, the formed conductive film layer covers the surface of the first insulating layer facing away from the chip and the portions of the pads exposed from the openings, and the thickness of the portion of the conductive film layer located on the side of the first insulating layer facing away from the chip is less than the thickness of the portion of the conductive film layer covering the pads, when the conductive film layer is etched, the portion of the conductive film layer covering the pads will not be completely etched, and the obtained conductive structures located in the openings are definitely in contact with the pads; compared with a solution in which a patterned photoresist layer is formed on the side of the first insulating layer facing away from the chip at first (the photoresist layer is provided with hollow regions), and then the conductive structure and the wiring on the conductive structure are simultaneously formed in the hollow regions of the photoresist layer, opening misalignment between the hollow regions and the first insulating layer caused by process errors can be avoided, which might have further led to insufficient exposure of the pads from the hollow regions which may further cause invalid electrical connection between the conductive structures and the pads, so that the electrical connection effect between the conductive structures and the pads can be ensured; and compared with a solution to broaden a size of the hollow regions of the photoresist layer to ensure that the hollow regions can fully expose the pads considering the process errors, short circuit between adjacent wirings in the redistribution structure caused by insufficient distance between adjacent hollow regions after the photoresist layer is removed can be avoided, according to the present application, openings in the first insulating layer do not need to be broadened while the electrical connection between the conductive structures and the pads can still be guaranteed, which can reduce a distance between adjacent wirings in the redistribution layer, hence when there is a small distance between adjacent pads of the chip, embodiments of the present application can still avoid the short circuit between adjacent wirings in the redistribution layer, which can improve yield rate of the semiconductor structure, reduce process accuracy requirements; in the semiconductor structure provided by the embodiments of the present application, a width of a portion of the wiring in the redistribution structure in contact with the conductive structure is less than a width of a surface of the conductive structure facing away from the chip, when there is a fixed distance between adjacent openings of the first insulating layer, the solution can help avoid short circuit between adjacent wirings, thereby improving yield rate of the semiconductor structure and reducing process accuracy requirements.

Details of one or more embodiments of the present application are set forth in the following figures and description. Other features, objects, and advantages of the present application will become apparent from the description, drawings, and claims.

### BRIEF DESCRIPTION OF DRAWINGS

FIG. 1 is a flowchart of a fabrication method for a semiconductor structure according to an example embodiment of the present disclosure.

FIG. 2 is a top view of a to-be-wired structure according to an example embodiment of the present disclosure.

FIG. 3 is a partial top view of the to-be-wired structure shown in FIG. 2.

FIG. 4A is a partial cross-sectional view of the to-be-wired structure shown in FIG. 2.

FIG. 4B is a top view of a to-be-wired structure according to another example embodiment of the present disclosure.

FIG. 5 is a top view of a to-be-wired structure according to another example embodiment of the present disclosure.

FIG. 6 is a top view of another to-be-wired structure according to another example embodiment.

FIG. 7 is a partial cross-sectional view of the to-be-wired structure shown in FIG. 5 and FIG. 6.

FIG. 8 is a schematic structural diagram of a first intermediate structure according to an example embodiment of the present disclosure.

FIG. 9 is a partial cross-sectional view of the first intermediate structure shown in FIG. 8.

FIG. 10 is a schematic structural diagram of a second intermediate structure according to an example embodiment of the present disclosure.

FIG. 11 is a partial cross-sectional view of the second intermediate structure shown in FIG. 10.

FIG. 12 is a partial cross-sectional view of a third intermediate structure according to an example embodiment of the present disclosure.

FIG. 13 is a partial cross-sectional view of a fourth intermediate structure according to an example embodiment of the present disclosure.

FIG. 14 is a schematic structural diagram of the fourth intermediate structure shown in FIG. 13.

FIG. 15 is a cross-sectional view of a fifth intermediate structure according to an example embodiment of the present disclosure.

FIG. 16 is a cross-sectional view of a sixth intermediate structure according to an example embodiment of the present disclosure.

FIG. 17 is a cross-sectional view of a seventh intermediate structure according to an example embodiment of the present disclosure.

FIG. 18 is a schematic structural diagram of the seventh intermediate structure shown in FIG. 17.

FIG. 19 is a cross-sectional view of an eighth intermediate structure according to an example embodiment of the present disclosure.

FIG. 20 is a schematic structural diagram of the eighth intermediate structure shown in FIG. 19.

FIG. 21 is a cross-sectional view of a ninth intermediate structure according to an example embodiment of the present disclosure.

FIG. 22 is a schematic structural diagram of a semiconductor structure according to an example embodiment of the present disclosure.

FIG. 23 is a partial cross-sectional view of the semiconductor structure shown in FIG. 22.

FIG. 24 is another partial cross-sectional view of the semiconductor structure shown in FIG. 22.

FIG. 25 is a partial cross-sectional view of a tenth intermediate structure according to an example embodiment of the present disclosure.

FIG. 26 is a partial cross-sectional view of a first intermediate structure according to another example embodiment of the present disclosure.

FIG. 27 is a partial cross-sectional view of a semiconductor structure according to another example embodiment of the present disclosure.

FIG. 28 is a partial cross-sectional view of an eleventh intermediate structure according to an example embodiment of the present disclosure.

FIG. 29 is a partial cross-sectional view of a twelfth intermediate structure according to an example embodiment of the present disclosure.

FIG. 30 is a partial cross-sectional view of a thirteenth intermediate structure provided by an example embodiment of the present disclosure.

FIG. 31 is a partial cross-sectional view of a first intermediate structure according to still another example embodiment of the present disclosure.

FIG. 32 is a partial cross-sectional view of a semiconductor structure according to still another exemplary embodiment of the present disclosure.

FIG. 33 is a schematic structural diagram of a semiconductor structure according to an example embodiment of the present disclosure.

FIG. 34 is a partial cross-sectional view of a semiconductor structure according to another example embodiment of the present disclosure.

FIG. 35 is a partial cross-sectional view of a semiconductor structure according to another example embodiment of the present disclosure.

FIG. 36 is a partial cross-sectional view of a semiconductor structure according to another example embodiment of the present disclosure.

### DETAILED DESCRIPTION

Example embodiments will be described in detail herein, examples of which are illustrated in the accompanying drawings. When the following description refers to the drawings, unless otherwise indicated, same numerals in different drawings indicate same or similar elements. The embodiments described in the following example embodiments do not represent all embodiments consistent with the present disclosure. Rather, they are merely examples of apparatuses and methods consistent with some aspects of the present disclosure as detailed in the appended claims.

The terminology used in the present disclosure is for the purpose of describing particular embodiments only and is not intended to limit the present disclosure. As used in the present disclosure and the appended claims, singular forms “a”, “the”, and “said” are also intended to include plural forms unless the context clearly indicates other meanings. It should also be understood that the term “and/or” as used herein refers to and encompasses any or all possible combinations of one or more associated listed items.

It should be understood that although the terms “first”, “second”, “third”, etc., may be used in the present disclosure to describe various information, these information should not be limited to these terms. These terms are only used to distinguish a same type of information from each other. For example, without departing from the scope of the present disclosure, “first information” may also be referred to as “second information”, and similarly, “second information” may also be referred to as “first information”. Depending on context, the word “if” as used herein may be interpreted as “when” or “upon” or “in response to determining”.

Some embodiments of the present disclosure are described in detail below with reference to the accompanying drawings. Without conflict, the following embodiments and features in the embodiments may be combined with each other.

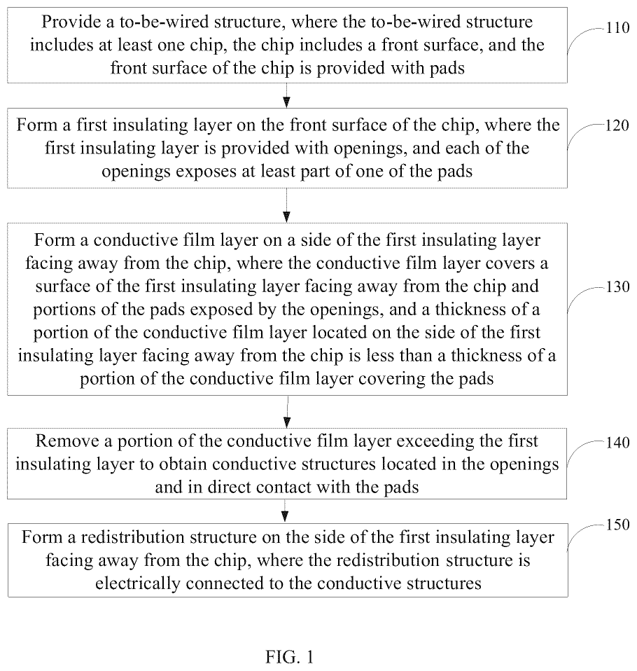

Embodiments of the present disclosure provide a fabrication method for a semiconductor structure and a semiconductor structure. Referring to FIG. 1, the fabrication method for the semiconductor structure includes following steps 110 to 150.

In step 110, providing a to-be-wired structure, where the to-be-wired structure includes at least one chip, the chip includes a front surface, and the front surface of the chip is provided with pads.

In step 120, forming a first insulating layer on the front surface of the chip, where the first insulating layer is provided with openings, and each of the openings exposes at least part of one of the pads.

In step 130, forming a conductive film layer on a side of the first insulating layer facing away from the chip, where the conductive film layer covers a surface of the first insulating layer facing away from the chip and portions of the pads exposed by the openings, and a thickness of a portion of the conductive film layer located on the side of the first insulating layer facing away from the chip is less than a thickness of a portion of the conductive film layer covering the pads.

In step 140, removing a portion of the conductive film layer exceeding the first insulating layer to obtain conductive structures located in the openings and in direct contact with the pads.

In step 150, forming a redistribution structure on the side of the first insulating layer facing away from the chip, where the redistribution structure is electrically connected to the conductive structures.

According to the fabrication method for the semiconductor structure and the semiconductor structure provided by the embodiments of the present disclosure, the formed conductive film layer covers the surface of the first insulating layer facing away from the chip and the portions of the pads exposed from the openings, and the thickness of the portion of the conductive film layer located on the side of the first insulating layer facing away from the chip is less than the thickness of the portion of the conductive film layer covering the pads, when the conductive film layer is etched, the portion of the conductive film layer covering the pads will not be completely etched, and the obtained conductive structures located in the openings are definitely in contact with the pads; compared with a solution in which a patterned photoresist layer is formed on the side of the first insulating layer facing away from the chip at first (the photoresist layer is provided with hollow regions), and then the conductive structure and the conductive traces on the conductive structure are simultaneously formed in the hollow regions of the photoresist layer, opening misalignment between the hollow regions and the first insulating layer caused by process errors can be avoided, which might have further led to non-exposure of the pads from the hollow regions which may further cause invalid electrical connection between the conductive structures formed in the hollow regions and the pads, so that the electrical connection effect between the conductive structures and the pads can be ensured; and compared with a solution to broaden a size of the hollow regions of the photoresist layer to ensure that the hollow regions can fully expose the pads considering the process errors, short circuit between adjacent wirings in the redistribution structure caused by insufficient distance between adjacent hollow regions after the photoresist layer is removed can be avoided, according to the present application, openings in the first insulating layer do not need to be broadened while the electrical connection between the conductive structures and the pads can still be guaranteed, which can reduce a distance between adjacent wirings in the redistribution layer, hence when there is a small distance between adjacent pads of the chip, embodiments of the present application can still avoid the short circuit between adjacent wirings in the redistribution layer, which can improve yield rate of the semiconductor structure, reduce process accuracy requirements.

The steps of the fabrication method for the semiconductor structure provided by the embodiments of the present disclosure will be described in detail below.

In step 110, providing a to-be-wired structure, where the to-be-wired structure includes at least one chip, the chip includes a front surface, and the front surface of the chip is provided with pads.

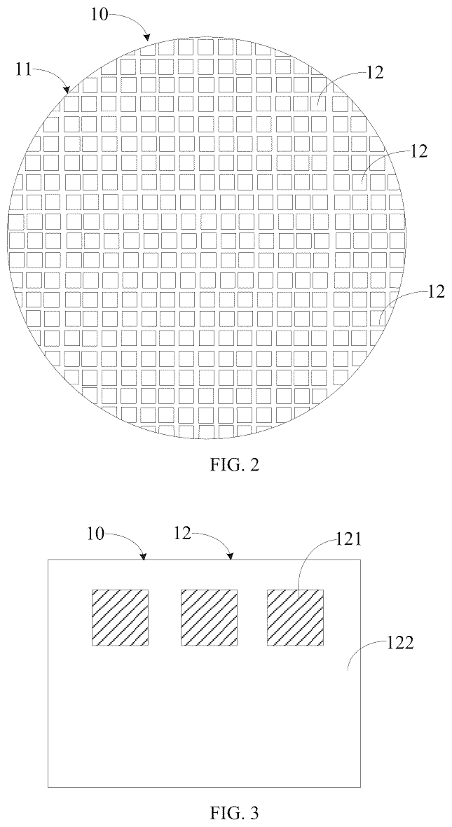

In an embodiment, referring to FIG. 1, the to-be-wired structure includes a plurality of chips. The step 110 of providing the to-be-wired structure includes: providing a wafer including a plurality of connected chips. By this step, the to-be-wired structure as shown in FIG. 2 can be obtained. The to-be-wired structure 10 shown in FIG. 2 is the wafer. Referring to FIG. 2, the wafer 11 includes a plurality of chips 12 connected together. The chips 12 being connected together refers to that at least part of layers of the chips 12 are an integral structure.

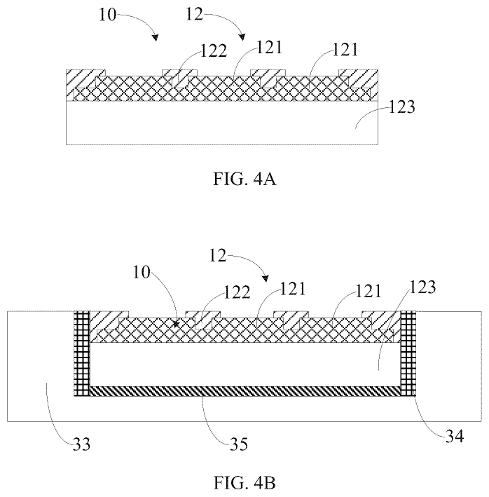

FIG. 3 and FIG. 4A are schematic partial structural diagrams of the to-be-wired structure 10, and are also schematic structural diagrams of one chip in the to-be-wired structure 10. Referring to FIG. 3 and FIG. 4A, the chip 12 includes a base layer 123, a plurality of pads 121 on the base layer 123, and an insulating film layer 122. A circuit is disposed in the base layer 123, and the pads 121 are electrically connected to the circuit in the base layer 123 to lead out the circuit in the base layer 123. The insulating film layer 122 covers edges of the pads 121, and a portion of each pad 121 is not covered by the insulating film layer 122. In the embodiment shown in FIG. 4A, adjacent pads 121 in the same chip 12 are connected. In other embodiments, adjacent pads 121 in the same chip 12 may be spaced apart.

In another embodiment, the step 110 of providing the to-be-wired structure includes following processes.

First, providing a silicon substrate and a chip, where the silicon substrate is provided with a groove, and a front surface of the chip faces away from a bottom of the groove.

Then, placing the chip in the groove.

Then, filling a glue material between the chip and a sidewall of the groove, and curing the glue material to form a dielectric layer.

By this step, the to-be-wired structure as shown in FIG. 4B can be obtained. As shown in FIG. 4B, the chip 12 is located in the groove of the silicon substrate 33, the dielectric layer 34 is filled between the chip 12 and the sidewall of the groove, and a back surface of the chip 12 is bonded to the bottom of the groove through a bonding layer 35.

In another embodiment, the step 110 of providing the to-be-wired structure includes following processes.

Providing a third carrier and a plurality of chips, and mounting the chips on the third carrier, where front surfaces of the chips face away from the third carrier.

In this embodiment, the chips may be obtained by cutting a wafer.

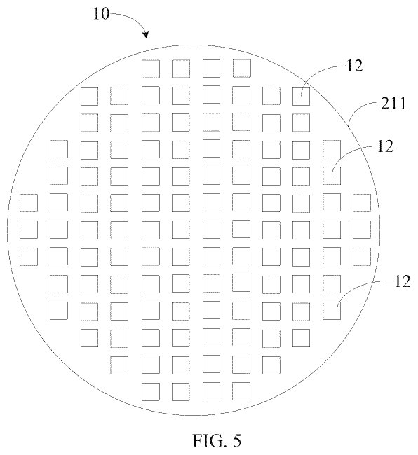

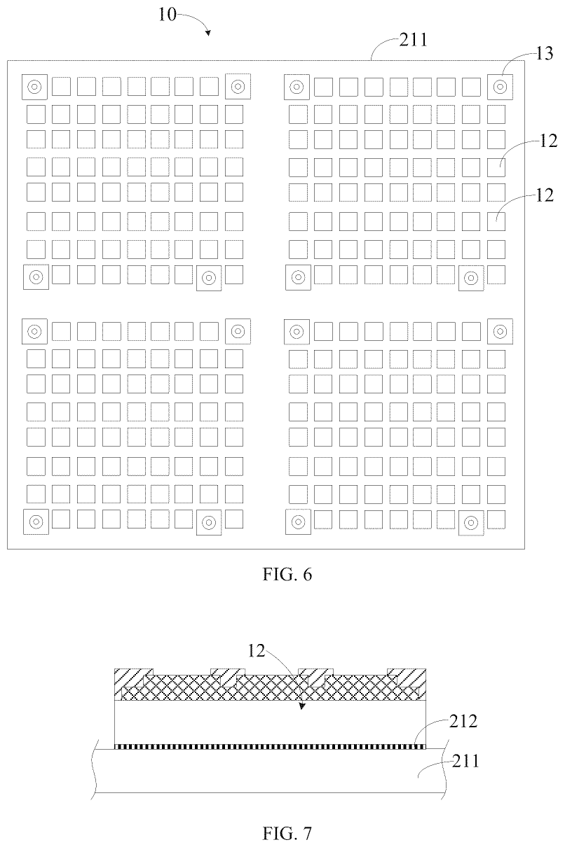

By this step, the to-be-wired structure as shown in FIG. 5 to FIG. 7 can be obtained. As shown in FIG. 5 to FIG. 7, the chips 12 are arranged on the third carrier 211 at intervals. A distance between adjacent chips 12 may be greater than that in the wafer. The third carrier 211 may be circular as shown in FIG. 5, or rectangular as shown in FIG. 6, or other shapes. The third carrier 211 may be a silicon substrate, a stainless steel substrate, a polymer substrate, or the like.

In an embodiment, the third carrier 211 is provided with a plurality of positioning portions 13. The positioning portions are used for positioning the chips 12 during mounting, which helps to improve precision of chip mounting.

In some embodiments, a back surface of each chip 12 is mounted on the third carrier 211 through a bonding layer 212. When the third carrier 211 is a silicon substrate, the bonding layer 212 may be a die attach film (DAF). When the third carrier 212 is a stainless steel substrate or a polymer substrate, the bonding layer 212 may be a double-sided adhesive. The bonding layer 212 may be made of a material that is easy to be stripped, so that subsequently the third carrier 211 can be stripped, for example, the bonding layer 212 may be made of a heat-separatable material that will lose adhesiveness by heating.

Steps 120 to 150 will be described in detail below by taking the to-be-wired structure shown in FIG. 2 as an example.

In step 120, forming a first insulating layer on the front surface of the chip, where the first insulating layer is provided with openings, and each of the openings exposes at least part of one of the pads.

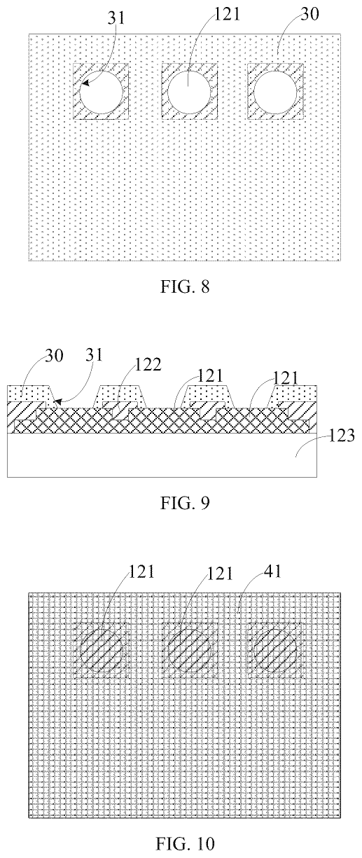

In an embodiment, the first intermediate structure shown in FIG. 8 and FIG. 9 may be obtained by step 120. Referring to FIG. 8 and FIG. 9, a plurality of openings 31 are disposed on the first insulating layer 30, the openings 31 may be in one-to-one correspondence with the pads 121, and each opening 31 exposes a portion of the corresponding pad 121. A material of the first insulating layer 30 may be resin or other insulating materials.

In this embodiment, a complete insulating material layer may be formed on the to-be-wired structure 10 at first, and then the complete insulating material layer is patterned to form the openings 31 to obtain the first insulating layer 30. For example, the openings 31 may be formed by etching the complete first insulating layer.

In step 130, forming a conductive film layer on a side of the first insulating layer facing away from the chip, where the conductive film layer covers a surface of the first insulating layer facing away from the chip, side surfaces of the openings and portions of the pads exposed by the openings, and a thickness of a portion of the conductive film layer located on the side of the first insulating layer facing away from the chip is less than a thickness of a portion of the conductive film layer covering the pads.

In an embodiment, the step 130 of forming the conductive film layer on the side of the first insulating layer facing away from the chip includes:

At first, a first seed layer is formed on the front surface of the chip, and the first seed layer covers the surface of the first insulating layer facing away from the chip, the side surfaces of the openings, and the portion of the pads exposed by the openings.

By this step, the second intermediate structure shown in FIG. 10 and FIG. 11 can be obtained. As shown in FIG. 10 and FIG. 11, the first seed layer 41 is a complete layer, and the first seed layer 41 covers an entire area of a surface of the first intermediate structure on the side of the first insulating layer facing away from the chip.

Then, the conductive film layer is formed based on the first seed layer.

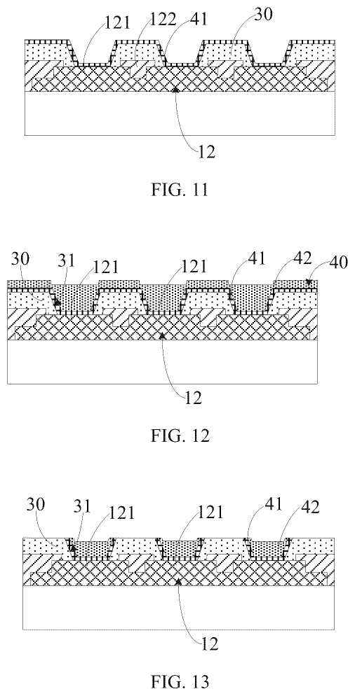

By this step, a third intermediate structure shown in FIG. 12 can be obtained. Referring to FIG. 12, the conductive film layer 40 includes the first seed layer 41 and a conductive layer 42 on a side of the first seed layer 41 facing away from the chip 12. The conductive layer 42 covers an entire area of the first seed layer 41.

For a surface of the conductive film layer facing away from the chip, a height of a partial surface of the conductive film layer 40 facing away from the chip 12 and in line with the openings 31 is slightly lower than a height of a partial surface of the conductive film layer 40 facing away from the chip and above the first insulating layer 30, and a difference between a distance from a partial surface of the conductive film layer 40 facing away from the chip and above the first insulating layer 30 to the chip 12, and a distance from a partial surface of the conductive film layer 40 facing away from the chip 12 and in line with the openings 31 to the chip is relatively small, for example, a ratio thereof ranges between 0.8-0.9. Since the difference between the distance from the partial surface of the conductive film layer 40 facing away from the chip and above the first insulating layer 30 to the chip 12, and the distance from the partial surface of the conductive film layer 40 facing away from the chip 12 and in line with the openings 31 to the chip is relatively small, in a subsequent process of etching the conductive film layer to remove a portion of the conductive film layer exceeding the first insulating layer, etching levels at different positions of the conductive film layer are of little difference, so that after the portion of the conductive film layer exceeding the first insulating layer is removed, the portion of the conductive film layer in the openings 31 will not be completely removed, and there is definitely a portion of the conductive film layer remained in the openings 31 and in direct contact with the pads, thereby ensuring the electrical connection between the subsequently formed conductive structures and the pads.

In an embodiment, the step of forming the conductive film layer based on the first seed layer may include: connecting the first seed layer 41 to a power, and performing electroplating to form a conductive layer 42 on a side of the first seed layer 41 facing away from the chip 12, to obtain the conductive film layer including the first seed layer 41 and the conductive layer 42.

A material of the conductive layer 42 includes a conductive material. When the conductive layer is formed by electroplating, a conductive material is deposited in the openings 31 at first, and after the openings 31 are substantially filled up with the conductive material, the conductive material starts to be deposited on the surface of the first insulating layer 30 facing away from the chip and above the opening 31, so that the difference between the distance from the partial surface of the conductive film layer 40 facing away from the chip and above the first insulating layer 30 to the chip 12, and the distance from the partial surface of the conductive film layer 40 facing away from the chip 12 and in line with the openings 31 to the chip is relatively small.

In step 140, removing a portion of the conductive film layer exceeding the first insulating layer to obtain conductive structures located in the openings and in direct contact with the pads.

The portion of the conductive film layer exceeding the first insulating layer refers to a portion of the conductive film layer beneath the surface of the conductive film layer facing away from the chip, and within a depth from a highest level of the surface of the conductive film layer facing away from the chip to a highest level of the surface of the first insulating layer facing away from the chip.

In an embodiment, the step 140 of removing the portion of the conductive film layer exceeding the first insulating layer to obtain the conductive structures located in the openings and in direct contact with the pads includes:
etching the conductive film layer to remove the portion of the conductive film layer exceeding the first insulating layer to obtain the conductive structures located in the openings and in direct contact with the pads.

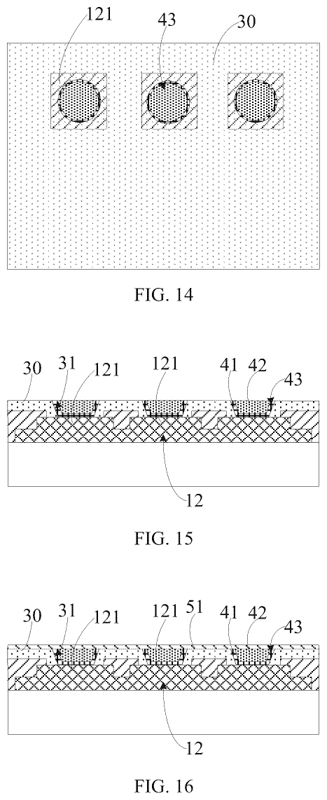

Further, the conductive film layer may be etched by a wet etching process to remove the portion of the conductive film layer exceeding the first insulating layer. Specifically, respective positions of the conductive film layer are etched simultaneously by using the wet etching process. Etched thickness in the respective positions of the conductive film layer is substantially same. After the conductive film layer is etched by using the wet etching process, a fourth intermediate structure shown in FIG. 13 and FIG. 14 may be obtained. Referring to FIG. 13 and FIG. 14, the portion of the conductive film layer 40 exceeding the first insulating layer 30 is removed, and the portion of the conductive film layer 40 within the openings 31 is retained.

As shown in FIG. 13, after the conductive film layer is etched by using the wet etching process, a height of a partial surface of the conductive film layer facing away from the chip 12 and located in the openings is lower than a height of a surface of the first insulating layer 30 facing away from the chip 12.

In another embodiment, removing the portion of the conductive film layer exceeding the first insulating layer includes: thinning the conductive film layer to remove the portion of the conductive film layer exceeding the first insulating layer. In some embodiments, the conductive film layer may be thinned by a grinding process.

In an embodiment, after removing the portion of the conductive film layer exceeding the first insulating layer, the fabrication method for the semiconductor structure further includes: thinning a portion of the conductive film layer in the openings and the first insulating layer, so that the surface of the first insulating layer facing away from the chip aligns with surfaces of the obtained conductive structures facing away from the chip.

By this step, a fifth intermediate structure shown in FIG. 15 can be obtained. As shown in FIG. 15, each conductive structure 43 includes a portion of the first seed layer 41 in each opening 31 and a portion of the conductive layer 42 in each opening 31.

The conductive film layer is etched, and after the portion of the conductive film layer exceeding the first insulating layer is removed, poor planeness is presented for the surface of the first insulating layer facing away from the chip and the surface of the conductive film layer facing away from the chip and within the openings, and by performing thinning, the planeness becomes better for a surface of the fifth intermediate structure facing away from the chip.

In step 150, forming a redistribution structure on the side of the first insulating layer facing away from the chip, where the redistribution structure is electrically connected to the conductive structures.

In an embodiment, the redistribution structure includes a redistribution layer on a side of the conductive structure facing away from the chip. The step 150 of forming the redistribution structure on the side of the first insulating layer facing away from the chip includes:

At first, forming a second seed layer on the side of the conductive structures facing away from the chip.

By this step, a sixth intermediate structure shown in FIG. 16 can be obtained. Referring to FIG. 16, the second seed layer 51 covers the surface of the conductive structures 43 facing away from the chip 12 and the surface of the first insulating layer 30 facing away from the chip 12. The second seed layer 51 is a complete layer covering the surface of the fifth intermediate structure on a side of the conductive structures 43 facing away from the chip.

Then, forming the redistribution layer based on the second seed layer.

In an embodiment, the step of forming the redistribution layer based on the second seed layer includes:
at first, disposing a patterned insulating material layer on a side of the second seed layer facing away from the chip, the insulating material layer is provided with a plurality of hollow portions, and each hollow portion exposes at least a portion of one conductive structure.

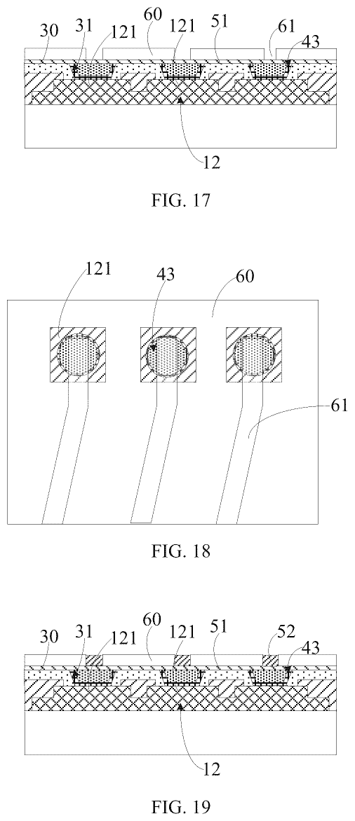

By this step, a seventh intermediate structure shown in FIGS. 17 and 18 can be obtained. FIG. 18 only shows portions the conductive structures 43, and the pads 121 not covered by the insulating film layer 122, and the insulating material layer 60. Referring to FIG. 17 and FIG. 18, the insulating material layer 60 is provided with a plurality of hollow portions 61, the hollow portions 61 may be strip-shaped, and an orthographic projection of each hollow portion 61 on the second seed layer 51 overlaps an orthographic projection of one conductive structure 43 on the second seed layer 51. The hollow portions 61 may be in one-to-one correspondence with the conductive structures 43, and an orthographic projection of each hollow portion 61 on the second seed layer 51 overlaps with an orthographic projection of the corresponding conductive structure 43 on the second seed layer 51.

Then, connecting the second seed layer to a power for electroplating to form trace structures in the hollow portions.

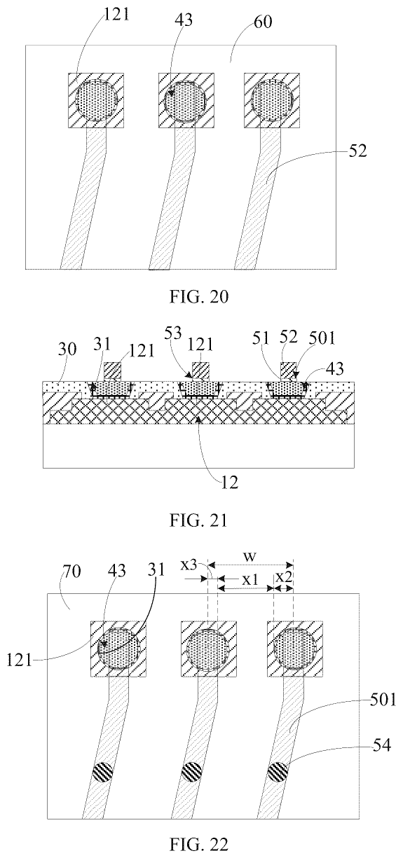

By this step, an eighth intermediate structure shown in FIGS. 19 and 20 can be obtained. As shown in FIG. 19 and FIG. 20, in each hollow portion, a trace structure 52 is formed. The eighth intermediate structure shown in FIG. 20 only illustrates portions of the conductive structures 43 and the pads 121 not covered by the insulating film layer 122, the insulating material layer 60 and the trace structures 52.

Then, removing the insulating material layer and a portion of the second seed layer not covered by the trace structures, where the redistribution layer includes the trace structures and the remaining second seed layer.

By this step, a ninth intermediate structure shown in FIG. 21 can be obtained. Referring to FIG. 21, the redistribution layer 53 includes a plurality of wirings 501, and each wiring 501 includes a remaining seed layer 51 and a trace structure 52.

In an embodiment, after the step of removing the insulating material layer and the portion of the second seed layer not covered by the redistribution structure, the step 150 of forming the redistribution structure on the side of the first insulating layer facing away from the chip further includes:
forming conductive pillars on a side of the redistribution layer facing away from the chip to obtain the redistribution structure including the redistribution layer and the conductive pillars.

The fabrication method for the semiconductor structure further includes: forming a second insulating layer; where the second insulating layer covers the redistribution layer and the conductive pillars, and surfaces of the conductive pillars facing away from the chip are exposed from the second insulating layer.

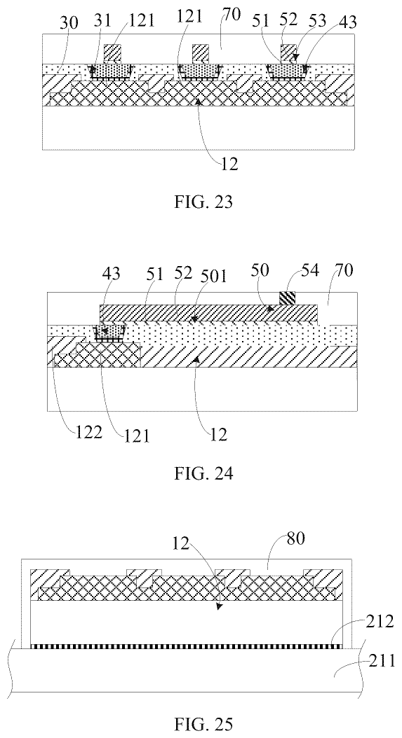

After forming the conductive pillars and the second insulating layer, the semiconductor structure shown in FIG. 22 to FIG. 24 can be obtained. FIG. 22 only shows the portions of the conductive structures 43 and the pads 121 not covered by the insulating film layer 122, the wirings 501, the conductive pillars 54 and the second insulating layer 70. Referring to FIGS. 22-24, the redistribution structure 50 includes the redistribution layer 53 and the conductive pillars 54. The second insulating layer 70 covers side portions of the redistribution layer 53 and the conductive pillars 54, and a surface of each conductive pillar 54 facing away from the chip is exposed from the second insulating layer 70.

In an embodiment, the step of forming the second insulating layer is performed before the step of forming the conductive pillars on the side of the redistribution layer facing away from the chip. The second insulating layer 70 is provided with through holes exposing a portion of the redistribution layer 53. Specifically, a plurality of through holes are formed in the second insulating layer 70, and each through hole exposes a portion of one wiring 501. Forming the conductive pillars on the side of the redistribution layer facing away from the chip includes: forming the conductive pillars on the side of the redistribution layer facing away from the chip in the through holes.

With such arrangement, the second insulating layer 70 is formed first, and then the conductive pillars are formed in the through holes of the second insulating layer 70, and compared with the solution in which the conductive pillars are formed first and then the second insulating layer 70 is formed, patterning processing does not need to be performed in the process of forming the conductive pillars, which helps to save process steps.

In an embodiment, when the to-be-wired structure includes more than one chips, the fabrication method for the semiconductor structure may further include: cutting the semiconductor structure to obtain a plurality of semiconductor sub-structures, and each semiconductor sub-structure may include one or more chips 12.

The present disclosure further provides another embodiment. In this embodiment, for step 120 to step 150, only differences from the above embodiments (the to-be-wired structure being the structure shown in FIG. 2) are described, and details will not be repeated herein.

In this embodiment, the to-be-wired structure is the structure shown in FIG. 5.

In an embodiment, the step 120 of forming the first insulating layer on the front surface of the chip includes:
forming an encapsulation layer at first, where the encapsulation layer covers side surfaces of the chip and a front surface of the chip. By this step, a tenth intermediate structure shown in FIG. 25 can be obtained. Referring to FIG. 25, the encapsulation layer 80 encapsulates the chip. The encapsulation layer may encapsulate all the chip 12 of the to-be-wired structure 10.

In an embodiment, before the encapsulation layer 80 is formed, pre-processes such as chemical cleaning, plasma cleaning and the like may be performed to remove impurities on surfaces of the chip 12 and the third carrier 211, so that the encapsulation layer 80 can be more closely connected to the chip 12 and the third carrier 211, thereby preventing delamination or cracking.

In an embodiment, if a thickness of the initially formed encapsulation layer is large, the step of forming the encapsulation layer may further include a step of thinning, so that the thickness of the thinned encapsulation layer is an expected thickness. The encapsulation layer may be thinned by a grinding process.

Then, a portion of the encapsulation layer on the front surface of the chip is patterned to form openings exposing the pads; and the first insulating layer includes a portion of the encapsulation layer on the front surface of the chip.

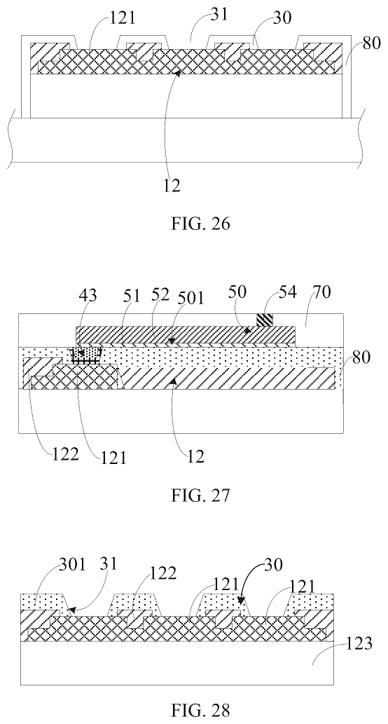

By this step, the first intermediate structure shown in FIG. 26 can be obtained.

In this embodiment, after the conductive pillars and the second insulating layer are formed, the third carrier 211 is removed.

The semiconductor structure obtained by this embodiment is shown in FIG. 27.

The present disclosure further provides another embodiment. In this embodiment, in step 120 to step 150, only differences from the above embodiments (the to-be-wired structure is the structure shown in FIG. 2) are described, and details will not be repeated herein.

In this embodiment, the to-be-wired structure is the structure shown in FIG. 2.

In an embodiment, after the step 120 of forming the first insulating layer on the front surface of the chip, the fabrication method for the semiconductor structure further includes:
at first, cutting the wafer to obtain semiconductor intermediate structures, where each of the semiconductor intermediate structures includes at least one chip.

By this step, an eleventh intermediate structure shown in FIG. 28 can be obtained. Referring to FIG. 28, after the wafer is cut, the first insulating layer 30 is divided into a plurality of sub-insulating layers 301, and each semiconductor intermediate structure includes a sub-insulating layer 301. The sub-insulating layer 301 is located on the front surface of the chip 12, and the openings 31 of the sub-insulating layer 301 exposes the pads 121 of the chip 12.

Then, mounting the semiconductor intermediate structure on a first carrier, where the first insulating layer faces the first carrier.

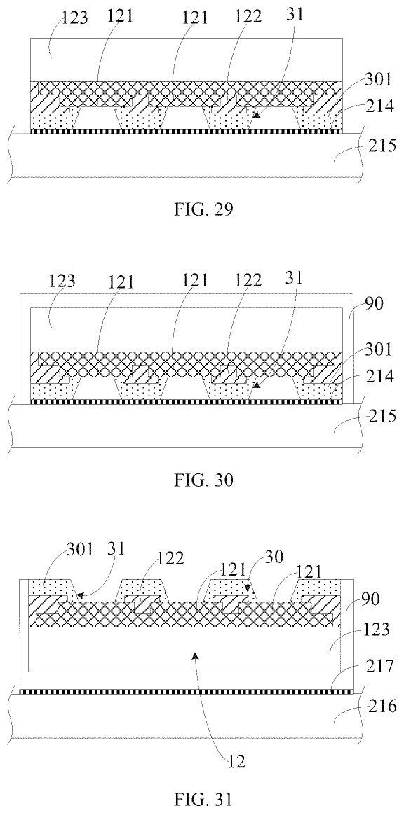

By this step, a twelfth intermediate structure shown in FIG. 29 can be obtained. Referring to FIG. 29, the semiconductor intermediate structure is mounted on the first carrier 215 through a bonding layer 214. The bonding layer 214 may include double-sided adhesive. The bonding layer 214 may be made of a material that is easy to be stripped, so that subsequently the first carrier 215 can be stripped, for example, the bonding layer 214 may be made of a heat-separatable material that will lose adhesiveness by heating.

Then, forming a molding layer, where the molding layer covers at least side surfaces of the semiconductor intermediate structures.

By this step, a thirteenth intermediate structure shown in FIG. 30 can be obtained. Referring to FIG. 30, the molding layer 90 encapsulates side portions of the semiconductor intermediate structure and the surface of the semiconductor intermediate structure facing away from the first carrier 215.

Then, stripping the first carrier to obtain a molding structure.

Then, mounting the molding structure on a second carrier, where the first insulating layer faces away from the second carrier.

By this step, a first intermediate structure shown in FIG. 31 can be obtained. Referring to FIG. 31, the first insulating layer 30 is located on a side of the chip 12 facing away from the second carrier 216. The thirteenth intermediate structure may be mounted on the second carrier 216 through a bonding layer 217. The bonding layer 217 may include double-sided adhesive. The bonding layer 217 may be made of a material that is easy to be stripped, so that subsequently the second carrier 216 can be stripped, for example, the bonding layer 217 may be made of a heat-separatable material that will lose adhesiveness by heating.

In this embodiment, after the conductive pillars and the second insulating layer are formed, the third carrier 211 is removed.

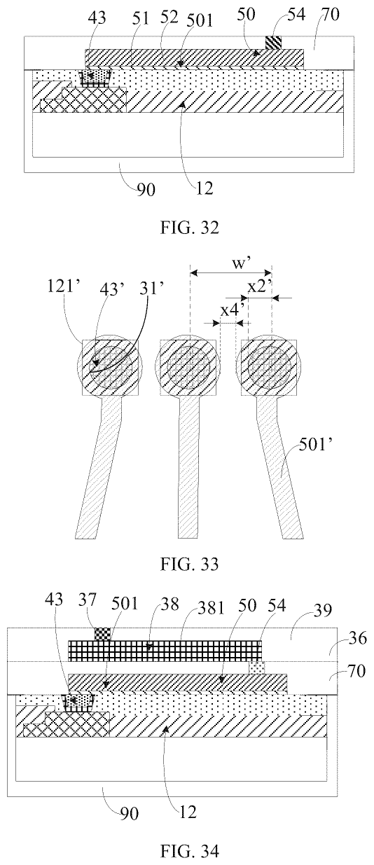

In this embodiment, the semiconductor structure finally obtained is shown in FIG. 32.

Referring back to FIG. 22, for the semiconductor structure obtained by the fabrication method for the semiconductor structure provided by the present disclosure, a distance between centers of two adjacent pads is w, a minimum distance between a wiring 501 and an adjacent opening 31 is x1, a radius of each opening 31 is x2, a half width of each wiring 501 is x3, and a process error is y, and a minimum value wₘᵢₙ of w, x1, x2, x3, and y satisfy the following formula:

$${w}_{min} = x 1 + x 2 + x 3 + y \qquad ( 1 )$$

Taking that the minimum distance x1 between the wiring 501 and the adjacent opening 31 being 15 μm, the radius x2 of each opening 31 being 25 μm, the width of each wiring 501 being 30 μm (i.e., half width x3=15 μm), and the process error y being 15 μm as an example, the minimum distance between centers of two adjacent pads is calculated by the above calculation formula (1) as wₘᵢₙ=70 μm. Taking that the minimum distance x1 between the wiring 501 and the adjacent opening 31 being 10 μm, the radius x2 of each opening 31 being 25 μm, the width of each wiring 501 being 30 μm (i.e., half width x3=15 μm), and the process error y being 15 μm as an example, the minimum distance between centers of two adjacent pads is calculated by the above calculation formula (1) as wₘᵢₙ=65 μm.

In a solution, in the semiconductor structure, the conductive structures in the openings and the wirings are formed in the same process step, specifically, firstly, a patterned photoresist layer (provided with a plurality of hollow regions) is formed on the side of the first insulating layer facing away from the chip, and then the conductive structures and the conductive traces located on the conductive structures are simultaneously formed in the hollow regions of the photoresist layer. In order to prevent misalignment between the hollow regions and the openings of the first insulating layer due to process errors, which might have caused that the hollow regions cannot expose the pads, and that the conductive structures formed in the hollow regions cannot be effectively electrically connected with the pads, a size of the hollow regions of the photoresist layer is broadened to ensure that the hollow regions can expose the pads. That is, the size of the hollow regions is large, and the wiring is formed in the hollow regions, and the size of the portion of the wiring aligning with the pad is large. As shown in FIG. 33, a width of the portion of the wiring 501′ in direct contact with the conductive structure 43′ is greater than a width of a surface of the conductive structure 43′ in contact with the wiring 501′, and the width of the portion of the wiring 501′ in direct contact with the conductive structure 43′ may be greater than a width of each opening 31′ and greater than a width of each pad 121′.

In this solution, a minimum distance between centers of two adjacent pads 121′ is w′, a minimum distance between adjacent wirings 501′ is x4′, a radius of each opening 31′ of the first insulating layer is x2′, and a process error is y′, and a minimum value w′ₘᵢₙ of w′, x4′, x2′, and y′ satisfy the following formula:

$${w}_{min}^{′} = x {4}^{′} + 2 x {2}^{′} + 2 {y}^{′} \qquad ( 2 )$$

In this solution, taking that a diameter of each opening 31′ of the first insulating layer being 50 μm (i.e., x2′=25 μm), the minimum distance x4′ between two adjacent wirings 501′ being 15 μm, and the process error y′ being 15 μm as an example, w′ₘᵢₙ=95 μm is calculated according to the above formula (2). That is, comparing this solution and the embodiment shown in FIG. 22, when the diameter of each opening of the first insulating layer and the process error remain unchanged, the minimum distance w′ₘᵢₙ between centers of two adjacent pads in this solution is greater than the minimum distance wₘᵢₙ between centers of two adjacent pads in the embodiment shown in FIG. 22. When the minimum distance w′ₘᵢₙ between the centers of two adjacent pads in this solution is made same as the minimum distance wₘᵢₙ between the centers of two adjacent pads in the present disclosure, for example, the minimum distance between the centers of two adjacent pads is 65 μm, then the process error y′ in this solution is calculated to be 0 based on the above formula (2), which cannot be realized by existing processes.

By comparing this solution with the fabrication method for the semiconductor structure provided by the present disclosure, it can be seen that the distance between centers of two adjacent pads of the semiconductor structure obtained by the fabrication method for the semiconductor structure provided by the present disclosure is reduced, and the requirement on the fabrication accuracy of wirings is reduced.

The embodiments of the present disclosure further provide a semiconductor structure. Referring to FIGS. 22-24, 27 and 32, the semiconductor structure includes a to-be-wired structure, a first insulating layer 30, conductive structures 43 and a redistribution structure 53.

The to-be-wired structure includes at least one chip 12, the chip 12 includes a front surface, and the front surface of the chip 12 is provided with pads 121. The first insulating layer 30 is provided on the front surface of the chip 12, where the first insulating layer 30 is provided with openings 31, and each opening 31 exposes at least part of one of the pads 121. The conductive structures 43 are located in the openings 31 and are in direct contact with the pads 121. The redistribution structure 53 is located on a side of the first insulating layer 30 facing away from the chip 12, the redistribution structure 53 includes a plurality of wirings 501, and the wirings 501 are in direct contact with the conductive structures 43. A width of a portion of each wiring 501 in contact with a corresponding conductive structure 43 is less than a width of a surface of the conductive structure 43 facing away from the chip 12.

According to the semiconductor structure provided by the embodiment of the present disclosure, a width of the part of the wiring of the redistribution structure in contact with the conductive structure is less than a width of a surface of the conductive structure facing away from the chip, and in a case that the distance between adjacent openings of the first insulating layer is given, a problem of short circuit of adjacent wirings can be avoided, the yield of the semiconductor structure can be improved, and the requirement on the process precision is reduced.

In an embodiment, as shown in FIGS. 22-24, 27 and 32, the redistribution structure 50 further includes conductive pillars 54 on a side of the wirings 501 facing away from the chip 12 and a second insulating layer 70, the second insulating layer 70 covers the wirings 501 and the conductive pillars 54, and surfaces of the conductive pillars 54 facing away from the chip 12 are exposed from the second insulating layer 70.

In an embodiment, as shown in FIG. 34, the semiconductor structure further includes a first redistribution layer 38 located on a side of the redistribution structure 50 facing away from the chip 12. The first redistribution layer 38 includes conductive traces 381 located on a side of the second insulating layer 70 facing away from the chip 12, and the conductive traces 381 are in direct contact with the conductive pillars 54. A width of a portion of each conductive trace 381 in contact with a corresponding conductive pillar 54 is less than a width of a surface of the conductive pillar 54 facing away from the chip 12.

Further, the semiconductor structure further includes a third insulating layer 36 and conductive pillars 37, the third insulating layer 36 is located on a side of the second insulating layer 70 facing away from the chip 12, and the conductive pillars 37 are located on a side of the conductive traces 381 facing away from the chip 12 and are in direct contact with the conductive traces 381. The third insulating layer 36 covers the conductive traces 381 and the conductive pillars 37, and surfaces of the conductive pillars 37 facing away from the chip 12 are exposed from the third insulating layer 36.

In an embodiment, as shown in FIG. 4B, the to-be-wired structure further includes a silicon substrate 33 and a dielectric layer 34; the silicon substrate 33 is provided with a groove, the chip 12 is located in the groove, and a front surface of the chip 12 faces away from a bottom of the groove; and the dielectric layer 34 is filled between the chip 12 and side walls of the groove.

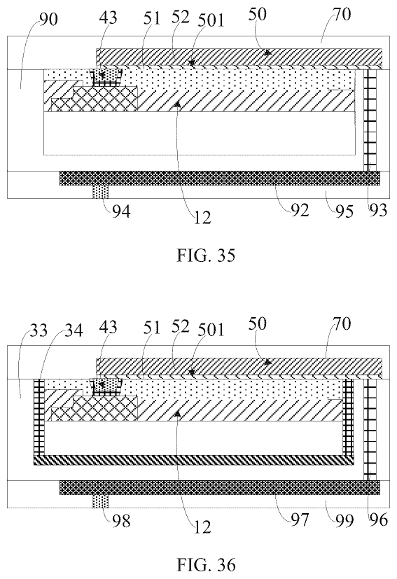

In an embodiment, as shown in FIG. 35, the to-be-wired structure further includes a molding layer 90, and the molding layer 90 covers at least side surfaces of the chip 12. In the illustrated embodiment, the molding layer 90 covers side surfaces and a back surface of the chip 12.

The molding layer 90 is provided with a first through hole penetrating through the molding layer, the semiconductor structure further includes a first conductive portion 93 located in the first through hole and a second redistribution layer 92 located in a side of the molding layer 90 facing away from the redistribution structure 50, and the second redistribution layer 92 is electrically connected to the redistribution structure 50 through the first conductive portion 93. Specifically, the second redistribution layer 92 is electrically connected to the wirings 501 of the redistribution structure 50 through the first conductive portion 93. In such way, the pads on the front surface of the chip 12 is electrically led to the back side of the chip 12 through the redistribution structure 50, the first conductive portion 93 and the second redistribution layer 92.

Further, the semiconductor structure further includes a conductive pillar 94 and a fourth insulating layer 95 located on a side of the molding layer 90 facing away from the redistribution structure 50, and the conductive pillar 94 is located on a side of the second redistribution layer 92 facing away from the chip 12 and is electrically connected to the second redistribution layer 92. The fourth insulating layer 95 covers the conductive pillars 94 and the second redistribution layer 92, and a surface of the conductive pillar 94 facing away from the chip 12 is exposed from the fourth insulating layer 95.

In another embodiment, as shown in FIG. 36, the to-be-wired structure further includes a silicon substrate 33 and a dielectric layer 34; the silicon substrate 33 is provided with a groove and a second through hole penetrating through the silicon substrate 33, the chip 12 is located in the groove, and the dielectric layer 34 is filled between the chip 12 and sidewalls of the groove.

The semiconductor structure further includes a second conductive portion 96 located in the second through hole and a third redistribution layer 97 located on a side of the silicon substrate 33 facing away from the redistribution structure 50; the third redistribution layer 97 is electrically connected to the redistribution structure 50 through the second conductive portion 96. Specifically, the third redistribution layer 97 is electrically connected to the wirings 501 of the redistribution structure 50 through the second conductive portion 96. In this way, the pads on the front side of the chip 12 are electrically led to the back side of the chip 12 through the redistribution structure 50, the second conductive portion 96 and the third redistribution layer 97.

Further, the semiconductor structure further includes a conductive pillar 98 and a fifth insulating layer 99 located on a side of a molding layer 90 facing away from the redistribution structure 50, and the conductive pillar 97 is located on a side of the third redistribution layer 97 facing away from the chip 12 and is electrically connected to the third redistribution layer 97. The fifth insulating layer 99 covers the conductive pillar 98 and the third redistribution layer 97, and a surface of the conductive pillar 98 facing away from the chip 12 is exposed from the fifth insulating layer 99.

The embodiments of the fabrication method for the semiconductor structure provided by the embodiments of the present disclosure and the embodiments of the semiconductor structure belong to the same inventive concept, and related details and beneficial effects may be described with reference to each other.

It should be noted that, the drawings provided by the embodiments of the present disclosure are merely schematic, and may have some differences from actual structures, for example, pads on the front side of the chip are not shown in the drawings, and in practice, the pads on the front side of the chip are electrically connected to the redistribution structure.

It should be noted that in the drawings, the dimensions of layers and regions may be exaggerated for clarity of illustration. Also, it is understood that when an element or layer is referred to as being “on” another element or layer, it may be directly on the other element, or intervening layers may be present therebetween. Additionally, it is understood that when an element or layer is referred to as being “under” another element or layer, it may be directly under the other element, or more than one intervening layer or element may be present therebetween. Additionally, it will be understood that when a layer or element is referred to as being “between” two layers or elements, it may be the only layer between two layers or elements, or more than one intermediate layer or element may also be present. Similar reference numerals indicate similar elements throughout.

Other embodiments of the present disclosure will be readily apparent to those skilled in the art upon consideration of the specification and practice of the disclosure herein. The present disclosure is intended to cover any variations, uses, or adaptations of the present disclosure that follow the general principles of the present disclosure and include common knowledge or conventional technical means in the art that is not disclosed in the present disclosure. The specification and embodiments are to be regarded as illustrative only, and the true scope and spirit of the present disclosure are indicated by the following claims.

It should be understood that the present disclosure is not limited to the precise structure described above and shown in the accompanying drawings, and various modifications and changes may be made without departing from the scope thereof. The scope of the present disclosure is limited only by the appended claims.

1. A fabrication method for a semiconductor structure, comprising:
providing a to-be-wired structure, wherein the to-be-wired structure comprises at least one chip, the chip comprises a front surface, and the front surface of the chip is provided with pads;
forming a first insulating layer on the front surface of the chip, wherein the first insulating layer is provided with openings, and each of the openings exposes at least part of one of the pads;
forming a conductive film layer on a side of the first insulating layer facing away from the chip, wherein the conductive film layer covers a surface of the first insulating layer facing away from the chip and portions of the pads exposed by the openings, and a thickness of a portion of the conductive film layer located on the side of the first insulating layer facing away from the chip is less than a thickness of a portion of the conductive film layer covering the pads;
removing a portion of the conductive film layer exceeding the first insulating layer to obtain conductive structures located in the openings and in direct contact with the pads; and
forming a redistribution structure on the side of the first insulating layer facing away from the chip, wherein the redistribution structure is electrically connected to the conductive structures.

2. The fabrication method for the semiconductor structure according to claim 1, wherein the to-be-wired structure comprises more than one chips; and providing the to-be-wired structure comprises:
providing a wafer, wherein the wafer comprises chips connected together.

3. The fabrication method for the semiconductor structure according to claim 2, wherein after forming the first insulating layer on the front surface of the chip, the fabrication method for the semiconductor structure further comprises:
cutting the wafer to obtain semiconductor intermediate structures, wherein each of the semiconductor intermediate structures comprises at least one of the chips;
mounting the semiconductor intermediate structure on a first carrier, wherein the first insulating layer faces the first carrier;
forming a molding layer, wherein the molding layer covers side surfaces of the semiconductor intermediate structure;
stripping the first carrier to obtain a molding structure; and
mounting the molding structure on a second carrier, wherein the first insulating layer faces away from the second carrier.

4. The fabrication method for the semiconductor structure according to claim 1, wherein providing the to-be-wired structure comprises:
providing a silicon substrate and a chip, wherein the silicon substrate is provided with a groove, and a front surface of the chip faces away from a bottom of the groove; and
placing the chip in the groove; and
filling a glue material between the chip and a sidewall of the groove, and curing the glue material to form a dielectric layer.

5. The fabrication method for the semiconductor structure according to claim 1, wherein providing the to-be-wired structure comprises: providing a third carrier and chips, and mounting the chips on the third carrier, wherein front surfaces of the chips face away from the third carrier; and
forming the first insulating layer on the front surface of the chip comprises: forming an encapsulation layer covering side surfaces of the chip and the front surface of the chip; and patterning a portion of the encapsulation layer located on the front surface of the chip to form the openings exposing the pads, wherein the first insulating layer comprises a portion of the encapsulation layer located on the front surface of the chip.

6. The fabrication method for the semiconductor structure according to claim 1, wherein forming the conductive film layer on the side of the first insulating layer facing away from the chip, wherein the conductive film layer covers the surface of the first insulating layer facing away from the chip, side surfaces of the openings, and the portions of the pads exposed by the openings comprises:
disposing a first seed layer on the surface of the first insulating layer facing away from the chip, the side surfaces of the openings, and the portions of the pads exposed by the openings; and
forming the conductive film layer based on the first seed layer.

7. The fabrication method for the semiconductor structure according to claim 6, wherein:
removing the portion of the conductive film layer exceeding the first insulating layer comprises: etching the conductive film layer to remove the portion of the conductive film layer exceeding the first insulating layer; or
removing the portion of the conductive film layer exceeding the first insulating layer comprises: thinning the conductive film layer to remove the portion of the conductive film layer exceeding the first insulating layer;
after removing the portion of the conductive film layer exceeding the first insulating layer, the fabrication method for the semiconductor structure further comprises: thinning a portion of the conductive film layer in the openings and the first insulating layer, so that the surface of the first insulating layer facing away from the chip aligns with surfaces of the obtained conductive structures facing away from the chip.

8. The fabrication method for the semiconductor structure according to claim 1, wherein the redistribution structure comprises a redistribution layer on a side of the conductive structures facing away from the chip;
forming the redistribution structure on the side of the first insulating layer facing away from the chip comprises:
forming a second seed layer on the side of the conductive structures facing away from the chip; and
forming the redistribution layer based on the second seed layer.

9. The fabrication method for the semiconductor structure according to claim 8, wherein the second seed layer covers surfaces of the conductive structures facing away from the chip and a surface of the first insulating layer facing away from the chip; and forming the redistribution layer based on the second seed layer comprises:
disposing a patterned insulating material layer on a side of the second seed layer facing away from the chip, wherein the insulating material layer is provided with hollow portions, and an orthographic projection of each of the hollow portions on the second seed layer overlaps with an orthographic projection of one of the conductive structures on the second seed layer;
connecting the second seed layer to a power for electroplating to form trace structures in the hollow portions; and
removing the insulating material layer and a portion of the second seed layer not covered by the trace structures to obtain the redistribution layer, wherein the redistribution layer comprises the trace structures and the remaining second seed layer.

10. The fabrication method for the semiconductor structure according to claim 9, wherein after removing the insulating material layer and the portion of the second seed layer not covered by the trace structures, forming the redistribution structure on the side of the first insulating layer facing away from the chip further comprises:
forming conductive pillars on a side of the redistribution layer facing away from the chip to obtain the redistribution structure comprising the redistribution layer and the conductive pillars;
wherein the fabrication method for the semiconductor structure further comprises:
forming a second insulating layer; wherein the second insulating layer covers the redistribution layer and the conductive pillars, and surfaces of the conductive pillars facing away from the chip are exposed from the second insulating layer;
forming the second insulating layer is performed before forming the conductive pillars on the side of the redistribution layer facing away from the chip; the second insulating layer is provided with through holes exposing the redistribution layer, and forming the conductive pillars on the side of the redistribution layer facing away from the chip comprises:
forming the conductive pillars on the side of the redistribution layer facing away from the chip in the through holes.

11. A semiconductor structure, comprising:
a to-be-wired structure, wherein the to-be-wired structure comprises at least one chip, the chip comprises a front surface, and the front surface of the chip is provided with pads;
a first insulating layer on the front surface of the chip, wherein the first insulating layer is provided with openings, and each of the openings exposes at least part of one of the pads;
conductive structures located in the openings and in direct contact with the pads; and
a redistribution structure located on a side of the first insulating layer facing away from the chip, wherein the redistribution structure comprises wirings, and the wirings are in direct contact with the conductive structures; for each of the wirings, a width of a portion of the wiring in contact with the corresponding conductive structure is less than a width of a surface of the corresponding conductive structure facing away from the chip.

12. The semiconductor structure according to claim 11, wherein the redistribution structure further comprises conductive pillars on a side of the wirings facing away from the chip and a second insulating layer, the second insulating layer covers the wirings and the conductive pillars, and surfaces of the conductive pillars facing away from the chip are exposed from the second insulating layer.

13. The semiconductor structure according to claim 12, further comprising a first redistribution layer on a side of the redistribution structure facing away from the chip;
the first redistribution layer comprises conductive traces, the conductive traces are in direct contact with the conductive pillars, and for each of the conductive traces, a width of a portion of the conductive trace in contact with the corresponding conductive pillar is less than a width of a surface of the corresponding conductive pillar facing away from the chip.

14. The semiconductor structure according to claim 11, wherein the to-be-wired structure further comprises a silicon substrate and a dielectric layer; the silicon substrate is provided with a groove, the chip is located in the groove, and the front surface of the chip faces away from a bottom of the groove; and the dielectric layer is filled between the chip and a sidewall of the groove.

15. The semiconductor structure according to claim 11, wherein,
the to-be-wired structure further comprises a molding layer, and the molding layer covers at least side surfaces of the chip; the molding layer is provided with a first through hole penetrating through the molding layer, and the semiconductor structure further comprises a first conductive portion located in the first through hole and a second redistribution layer located on a side of the molding layer facing away from the redistribution structure; and the second redistribution layer is electrically connected to the redistribution structure through the first conductive portion; or
the to-be-wired structure further comprises a silicon substrate and a dielectric layer; the silicon substrate is provided with a groove and a second through hole penetrating through the silicon substrate, the chip is located in the groove, and the dielectric layer is filled between the chip and a side wall of the groove; the semiconductor structure further comprises a second conductive portion located in the second through hole and a third redistribution layer located on a side of the silicon substrate facing away from the redistribution structure; and the third redistribution layer is electrically connected with the redistribution structure through the second conductive portion.
